(19) United States
(12) Patent Application Publication
(10) Pub. No.: US 2021/0378142 A1
(43) Pub. Date: Dec. 2, 2021

(54) HEAT DISSIPATION DEVICE AND SERVER USING SAME

(71) Applicant: HONGFUJIN PRECISION ELECTRONICS(TIANJIN)CO.,LTD., Tianjin (CN)

(72) Inventors: YA-NI ZHANG, Tianjin (CN); ZHAO-HUI ZHEN, Tianjin (CN); MING-HUA DUAN, Tianjin (CN); JIA-HONG WU, New Taipei (TW)

(21) Appl. No.: 17/329,855

(22) Filed: May 25, 2021

(30) Foreign Application Priority Data
May 26, 2020 (CN) 202010452322.5

(51) Int. Cl. H05K 7/20

(52) U.S. Cl. CPC H05K 7/20272

(57) ABSTRACT

A server with a cooling system which can maintain a constant and preferred operating temperature for the server includes a computer and a heat dissipation device for dissipating heat generated by the computer. The heat dissipation device includes a liquid tank and a heat exchange device. The liquid tank defines an accommodating cavity for accommodating non-conductive cooling liquid and the computer. The heat exchange device is connected to the liquid tank to exchange heat with the non-conductive cooling liquid in the liquid tank.

### FIELD

The subject matter herein generally relates to cooling, including heat dissipation device for server.

### BACKGROUND

Servers generate a good deal of heat during operation. Generally, fans and holes are used to drive the heat to the outside of the server. However, as computing becomes faster and broader, more and more heat is generated by the servers during operation. Dissipating heat through fans and holes does not dissipate the heat quickly enough, and the calculation speed of the server may ultimately be affected.

Therefore, there is room for improvement within the art.

### BRIEF DESCRIPTION OF THE DRAWINGS

Implementations of the present technology will now be described, by way of embodiments with reference to the attached figures.

FIG. 1 is an external and isometric view of a server according to an embodiment.

FIG. 2 is similar to FIG. 1, but viewed from another viewpoint.

FIG. 3 is an isometric view of the interior of the server of FIG. 1.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale, and the proportions of certain parts may be exaggerated to better show details and features of the present disclosure. The disclosure is by way of embodiments and not by way of limitation in the figures of the accompanying drawings, in which like references indicate similar elements. It should be noted that references to “an” or “one” embodiment in this disclosure are not necessarily to the same embodiment, and such references mean “at least one.”

Several definitions that apply throughout this disclosure will now be presented.

The term “substantially” is defined to be essentially conforming to the particular dimension, shape, or other feature that the term modifies, such that the component need not be exact. For example, “substantially cylindrical” means that the object resembles a cylinder, but can have one or more deviations from a true cylinder. The term “comprising,” when utilized, means “including, but not necessarily limited to”; it specifically indicates open-ended inclusion or membership in the so-described combination, group, series, and the like. References to “a plurality of” and “a number of” mean “at least two.”

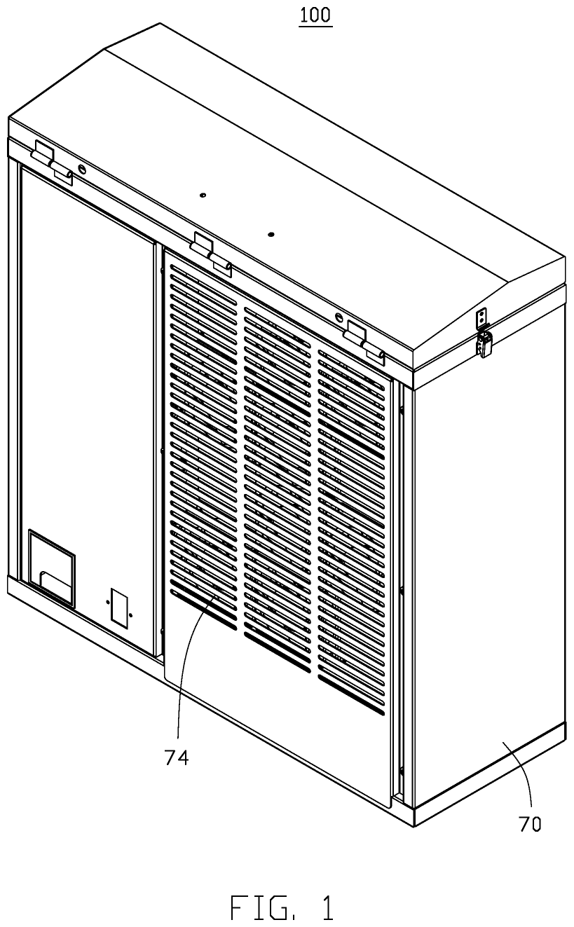

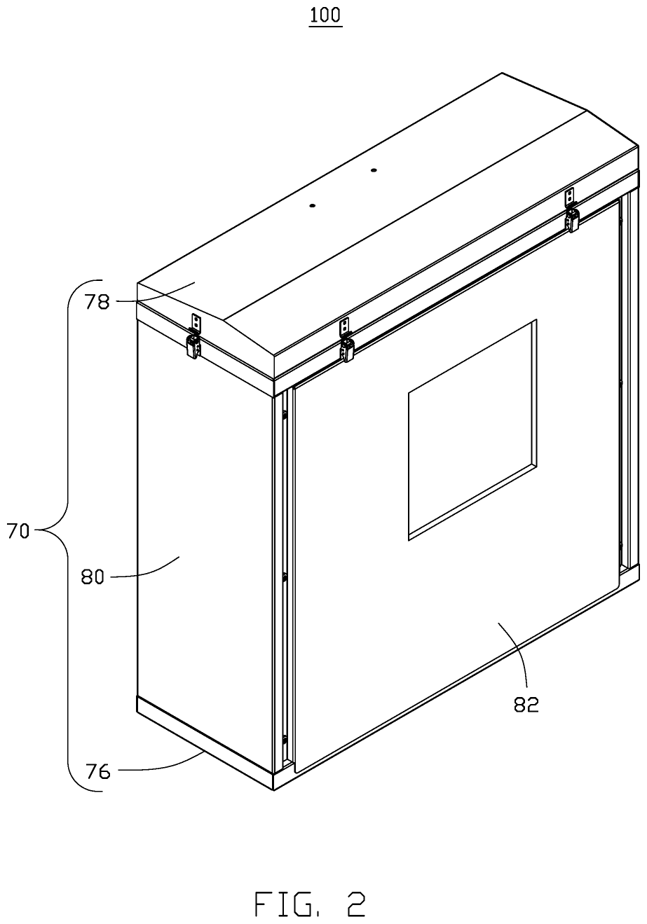

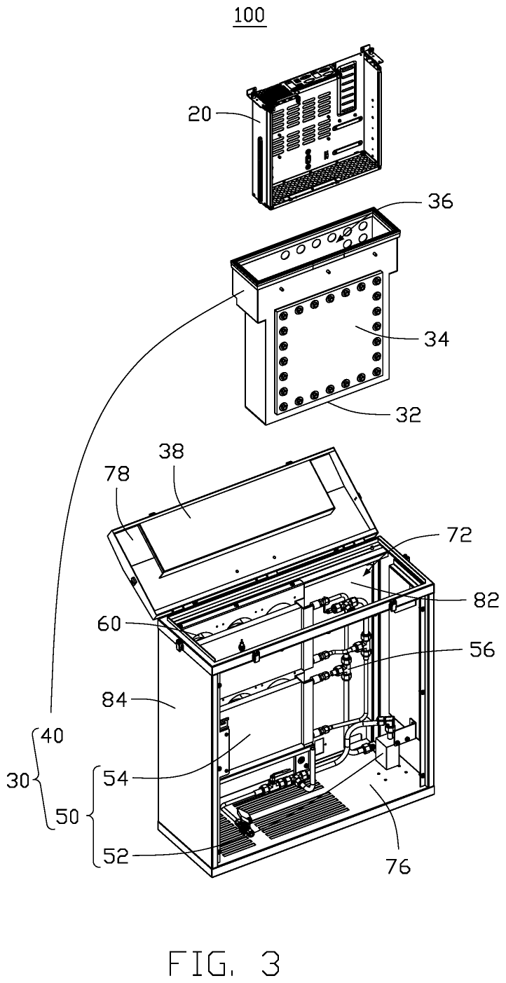

Referring to FIG. 1 to FIG. 3, a server 100 is disclosed. The server 100 includes a computer 20 and a heat dissipation device 30. The computer 20 includes a number of heat-generating electronic components. The heat dissipation device 30 dissipates heat from the computer 20 in such a way as to stabilize the proper operation of the computer 20 at all times.

The heat dissipation device 30 includes a liquid tank 40 and a heat exchange device 50. The liquid tank 40 includes a bottom plate 32 and a side plate 34 extending around the edge of the bottom plate 32. The bottom plate 32 and the side plate 34 form an accommodating cavity 36 for containing non-conductive cooling liquid. In one embodiment, the non-conductive cooling liquid is oil. The cooling liquid immerses the computer 20 when the computer 20 is in the accommodating cavity 36, so as to absorb the heat generated by the computer 20, to reduce the temperature of the computer 20. The heat exchange device 50 is connected to the liquid tank 40. The heat exchange device 50 is configured to exchange heat with the non-conductive cooling liquid in the liquid tank 40. The liquid tank 40 further includes a sealing cover 38. The sealing cover 38 is used to seal the accommodating cavity 36 after the computer 20 is placed in the accommodating cavity 36, to prevent the non-conductive cooling liquid from flowing out of the liquid tank 40.

In one embodiment, the heat exchange device 50 includes at least one pump 52 and at least one radiator 54. One end of the pump 52 is in communication with a first position of the liquid tank 40, the other end of the pump 52 is in communication with a first position of the housing of the radiator 54. A second position of the housing of the radiator 54 is in communication with a second position of the liquid tank 40, so that the liquid tank 40, the pump 52, and the radiator 54 form a loop to deliver the non-conductive cooling liquid in the liquid tank 40 to the radiator 54 though the pump 52. The heat of the non-conductive cooling liquid is dissipated through the radiator 54, and the non-conductive cooling liquid is returned to the liquid tank 40 after the heat exchange. In one embodiment, the heat exchange device 50 includes one pump 52 and a plurality of radiators 54. One end of the pump 52 communicates with the plurality of radiators 54 through one or more three-way joints 56, and each three-way joint 56 communicates with two of the radiators 54. The second position of the plurality of radiators 54 is being connected to the second position of the liquid tank 40 through one or more three-way joints 56. In one embodiment, the heat exchange device 50 further includes heat sinks fixed on the shell of the radiator 54. In this way, the heat exchange device 50 improves the speed and efficiency of heat exchange between the heat exchange device 50 and the non-conductive cooling liquid.

In one embodiment, the first position of the radiator 54 is located at the top of the radiator 54, and the second position of the radiator 54 is located at the bottom of the radiator 54. The first position of the liquid tank 40 is located at the bottom of the liquid tank 40, and the second position of the liquid tank 40 is located at the top of the liquid tank 40. Since the non-conductive cooling liquid flows from the bottom of the liquid tank 40 into the top of the radiator 54 and then flows to the bottom of the radiator 54 and then flows into the top of the liquid tank 40, the circulation efficiency of the non-conductive cooling liquid can be increased, so that more heat is dissipated from the radiator 54.

The heat dissipation device 30 further includes at least one fan 60. The at least one fan 60 faces the at least one radiator 54 to dissipate the heat emitted by the radiator 54 and improve the heat exchange efficiency of the radiator 54. The server 100 further includes a housing 70. The housing 70 defines a receiving cavity 72. The heat exchange device 50 is placed in the receiving cavity 72 and fixed in the housing 70. The at least one fan 60 is fixed inside the casing 70. A plurality of ventilation holes 74 are formed on the housing 70. The plurality of ventilation holes 74 are arranged to face the at least one fan 60, so that the at least one fan 60 dissipates the heat emitted by the heat sink 54 to the outside of the housing 70 through the plurality of ventilation holes 74.

The housing 70 includes a bottom shell 76, a top shell 78, and a side shell 80 connected between the bottom shell 76 and the top shell 78. In one embodiment, the side shell 80 extends along the edge of the bottom shell 76 toward the top shell 78 and is partially connected to the top shell 78. The bottom shell 76 and the side shell 80 form the accommodating cavity 72. The sealing cover 38 is fixed on the inner side of the top shell 78. The top shell 78 is used to seal the receiving cavity 72 after the heat exchange device 50 and the computer 20 are placed in the receiving cavity 72. In one embodiment, the side shell 80 includes two opposite first plates 82 and two opposite second plates 84. The two first plates 82 are vertically connected to the two ends of the two second plates 84. The top shell 78 is rotatably connected with one of the two first plates 82, and is fixedly connected with the other first plate 82 when the receiving cavity 72 is shielded. In an embodiment, the top shell 78 is fixedly connected to the first plate 82 by a buckle when the accommodating cavity 72 is shielded, so that no tools are needed when the top shell 78 is opened and fixed.

The server 100 and the heat dissipating device 30 absorb the heat of the computer 20 placed in the liquid tank 40 through the non-conductive cooling liquid and exchange heat through the heat exchange device 50, so that the heat of the computer 20 can be dissipated to the computer 20 or the server 100 in time and improved heat dissipation efficiency.

The embodiments shown and described above are only examples. Therefore, many commonly-known features and details are neither shown nor described. Even though numerous characteristics and advantages of the present technology have been set forth in the foregoing description, together with details of the structure and function of the present disclosure, the disclosure is illustrative only, and changes may be made in the detail, including in matters of shape, size, and arrangement of the parts within the principles of the present disclosure, up to and including the full extent established by the broad general meaning of the terms used in the claims. It will, therefore, be appreciated that the embodiments described above may be modified within the scope of the claims.

What is claimed is:

1. A heat dissipation device configured to dissipate the heat generated by a computer, comprising:
a liquid tank, defining an accommodating cavity for accommodating non-conductive cooling liquid and the computer; and
a heat exchange device, connected to the liquid tank and configured to exchange heat with the non-conductive cooling liquid in the liquid tank.

2. The heat dissipation device of claim 1, wherein the heat exchange device comprises at least one pump and at least one radiator, one end of the pump is in communication with a first position of the liquid tank, the other end of the pump is in communication with a first position of the housing of the radiator, a second position of the housing of the radiator is in communication with a second position of the liquid tank, the liquid tank, the pump, and the radiator form a loop.

3. The heat dissipation device of claim 2, wherein the heat exchange device comprises one pump and a plurality of radiators, one end of the pump communicates with the plurality of radiators.

4. The heat dissipation device of claim 3, wherein one end of the pump communicates with the plurality of radiators through one or more three-way joints, and each three-way joint communicates with two of the radiators.

5. The heat dissipation device of claim 2, wherein the first position of the radiator is located at the top of the radiator, and the second position of the radiator is located at the bottom of the radiator, the first position of the liquid tank is located at the bottom of the liquid tank, and the second position of the liquid tank is located at the top of the liquid tank.

6. The heat dissipation device of claim 2, wherein the heat dissipation device further comprises at least one fan, the at least one fan faces the at least one radiator.

7. A server comprising:
a computer;
a heat dissipation device, configured to dissipate the heat generated by the computer;
the heat dissipation device comprising:
a liquid tank, defining an accommodating cavity for accommodating non-conductive cooling liquid and the computer; and
a heat exchange device, connected to the liquid tank and configured to exchange heat with the non-conductive cooling liquid in the liquid tank.

8. The server of claim 7, wherein the server further includes a housing, the housing defines a receiving cavity, the heat exchange device is placed in the receiving cavity and fixed in the housing, a plurality of ventilation holes are formed on the housing, the plurality of ventilation holes are arranged facing the heat dissipation device.

9. The server of claim 8, wherein the housing comprises a bottom shell, a top shell, and a side shell connected between the bottom shell and the top shell, the top shell is rotatably connected with side shell, the top shell is configured to shield the receiving cavity and is fixedly connected with the side shell when the receiving cavity is shielded.

10. The server of claim 7, wherein the non-conductive cooling liquid is oil.

11. The server of claim 7, wherein the heat exchange device comprises at least one pump and at least one radiator, one end of the pump is in communication with a first position of the liquid tank, the other end of the pump is in communication with a first position of the housing of the radiator, a second position of the housing of the radiator is in communication with a second position of the liquid tank, the liquid tank, the pump, and the radiator form a loop.

12. The heat dissipation device of claim 11, wherein the heat exchange device comprises one pump and a plurality of radiators, one end of the pump communicates with the plurality of radiators.

13. The heat dissipation device of claim 12, wherein one end of the pump communicates with the plurality of radiators through one or more three-way joints, and each three-way joint communicates with two of the radiators.

14. The heat dissipation device of claim 11, wherein the first position of the radiator is located at the top of the radiator, and the second position of the radiator is located at the bottom of the radiator, the first position of the liquid tank is located at the bottom of the liquid tank, and the second position of the liquid tank is located at the top of the liquid tank.

15. The heat dissipation device of claim 11, wherein the heat dissipation device further comprises at least one fan, the at least one fan faces the at least one radiator.
